(19) United States
(12) Patent Application Publication
(10) Pub. No.: US 2026/0282267 A1
(43) Pub. Date: Sep. 17, 2026

(54) MODULAR PLINTH SYSTEM

(71) Applicant: Vertiv Corporation, Westerville, OH (US)

(72) Inventors: Mahesh Pimpale, Ahmednagar (IN); Rahul Musale, Pune (IN); Akshay D. Shah, Pune (IN); Kishan Jaysukh-Bhai Jethva, Pune (IN)

(21) Appl. No.: 19/561,938

(22) Filed: Mar. 10, 2026

(30) Foreign Application Priority Data
Mar. 12, 2025 (IN) 202511022294

(51) Int. Cl. H05K 7/18

(52) U.S. Cl. CPC H05K 7/186

(57) ABSTRACT

A modular plinth system, includes a plurality of plinth modules, wherein each of the plurality of the channel plinth module are aligned adjacently at a predetermined distance from each other to form an outer frame structure of variable size, and wherein the outer side wall of each of the plurality of the plinth module include at least one plinth sliding slot. The system further comprises a plurality of support brackets, wherein each of the support brackets includes a bracket sliding slot, and a bracket with one or more fastening mechanism, wherein each of the support bracket is placed over the outer side walls of two adjacently placed plinth modules to align the at least one plinth sliding slot with the bracket sliding slot, and fasten the at least one plinth sliding slot with the bracket sliding slot using the bracket with the one or more fastening mechanism.

### CROSS-REFERENCE TO RELATED APPLICATIONS

The present application claims the benefit under 35 U.S.C. § 119(e) of Indian Provisional Patent Application Serial Number 202511022294 filed Mar. 12, 2025, which is incorporated herein by reference in the entirety.

### TECHNICAL FIELD

The present disclosure generally relates to plinths for Outside Plant (OSP) system. More particularly, the present disclosure relates to a modular plinth configured to accommodate varying cabinet footprint sizes, thereby reducing inventory complexity, simplifying installation, and enhancing structural flexibility.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also correspond to implementations of the claimed technology.

Plinths serve as a stable base for cabinets and provide space for cable entry. The plinths may be open-frame or enclosed with sheet metal side walls. Existing outdoor telecommunications and utility cabinets, commonly deployed in Outside Plant (OSP) environments, rely on plinths for structural support, load distribution, and environmental protection. However, conventional plinths are manufactured in fixed sizes (e.g., 32″, 34″, 36″, 38″), requiring users to maintain multiple inventory stock-keeping units, leading to increased storage costs, logistical challenges, and reduced flexibility in adapting to new or modified cabinet designs.

Accordingly, there is a need for a modular plinth system that accommodates multiple cabinet footprint sizes, minimizing inventory requirements, enabling rapid adjustments, and simplifying assembly.

### SUMMARY OF THE INVENTION

This summary is provided to introduce aspects related to a modular plinth system for a server cabinet or OSP cabinet. This summary is not intended to identify essential features of the present subject matter, nor is it intended for use in determining or limiting the scope of the present subject matter.

In an embodiment of the present invention, a modular plinth system comprises a plurality of plinth modules, wherein each plinth module is aligned adjacent to another plinth module at a predetermined distance so as to collectively form an outer frame structure of variable size. An outer side wall of each plinth module includes at least one plinth sliding slot. The modular plinth system further comprises a plurality of support brackets or bracket bodies, wherein each support bracket includes a bracket sliding slot and a bracket provided with or configured to receive one or more fastening mechanisms. Each support bracket is positioned over the outer side walls of two adjacent plinth modules such that the plinth sliding slot is aligned with the bracket sliding slot, and the aligned slots are fastened using the bracket and one or more fastening mechanisms, thereby securing the plinth modules to define the outer frame structure.

In one embodiment of the present invention, the modular plinth system includes a plurality of plinth modules, wherein the plinth modules are configured as rectangular channel plinth modules.

In one embodiment of the present invention, the plurality of plinth modules is arranged to form an outer frame structure having a shape selected from at least one of a square shape or a rectangular shape, with the outer frame structure being configurable to different sizes.

In one embodiment of the present invention, each support bracket is configured to be placed over the outer side walls of two adjacent plinth modules.

In one embodiment of the present invention, each support bracket includes a bracket sliding slot provided to align with a plinth sliding slot provided on a corresponding plinth module.

In one embodiment of the present invention, the modular plinth system includes a fastening mechanism, wherein the fastening mechanism comprises a bolt-type fastening member.

In one embodiment of the present invention, each plinth module includes a plinth sliding slot provided on an outer side wall of the plinth module.

In one embodiment of the present invention, each support bracket includes a bracket body configured to receive the fastening mechanism.

In one embodiment of the present invention, the fastening mechanism is removably coupled to the support bracket.

In yet another embodiment of the present invention, the plurality of plinth modules together defines the outer frame structure of the modular plinth system.

In one or more embodiments of the present invention, each plinth module includes perpendicular extending walls, and wherein each of the perpendicular extending walls includes a corresponding plinth sliding slot.

In one or more embodiments of the present invention, in a square arrangement of four plinth modules, plinth sliding slots of adjacent walls of the plinth modules are aligned on a common plane.

In one or more embodiments of the present invention, the fastening mechanism includes a nut assembly configured to be tightened to lock the plinth modules in a desired position.

In one or more embodiments of the present invention, the modular plinth system further includes one or more supporting blocks mounted within the outer frame structure and configured to provide additional structural support to the modular plinth system.

In one or more embodiments of the present invention, the one or more supporting blocks include one or more supporting block sliding slots alignable with a support bracket to adjust according to a size of the outer frame structure.

In an embodiment of the present invention, a modular plinth system comprises a plurality of rectangular channel plinth modules, wherein the rectangular channel plinth modules are aligned adjacently at a selected distance from each other to form an outer frame structure, wherein the outer frame structure is selected from a square shape or a rectangular shape, wherein each rectangular channel plinth module includes perpendicular extending walls, and wherein each wall includes at least one plinth sliding slot provided on an outer side wall of the plinth module; and a plurality of support brackets, wherein one or more support brackets or the plurality of support brackets are placed over the outer side walls of two adjacently placed rectangular channel plinth modules, wherein the one or more support brackets includes: a bracket body: a bracket sliding slot, wherein the plinth sliding slots of the rectangular channel plinth modules and the bracket sliding slot of the support bracket are aligned on a common plane: and a fastening mechanism, wherein the fastening mechanism includes a bolt-type fastening member including a nut assembly, wherein loosening the fastening mechanism allows sliding movement of the rectangular channel plinth modules to adjust the selected distance, and tightening the nut assembly locks the rectangular channel plinth modules in a desired position, wherein the support brackets are fastened with the walls of the rectangular channel plinth modules using the bracket body and the fastening mechanism to rigidly form the outer frame structure; and supporting blocks mounted within the outer frame structure, the supporting blocks providing additional structural support and including sliding slots alignable with the support brackets for adjustment according to a size of the outer frame structure.

In one or more embodiments of the present invention, four rectangular channel plinth modules are arranged in a square arrangement, and wherein the plinth sliding slots of adjacent walls of the rectangular channel plinth modules are aligned on a common plane, the supporting blocks are mounted within the outer frame structure to provide structural strength and stability to the modular plinth system during installation of cabinets.

In one or more embodiments of the present invention, the fastening mechanism is removably coupled to the support bracket to allow adjustment of the outer frame structure to accommodate different footprint sizes of cabinets.

In one or more embodiments of the present invention, the bolt-type fastening member includes a T-bolt assembly configured to engage both the bracket sliding slot and the plinth sliding slot.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIG. 1 illustrates perspective views of existing plinth systems.

FIG. 2 illustrates a perspective view of a modular plinth system, in accordance with an embodiment of the present invention.

FIG. 3 illustrates a perspective view of the modular plinth system configured to support varying sizes of Outside Plant (OSP) cabinet, in accordance with an embodiment of the present invention.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label, irrespective of the suffix.

### DETAILED DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

Outside Plant (OSP) cabinets are essential components in telecommunications and utility networks, providing protection and housing for critical equipment. OSP cabinets are generally placed on a plinth which provides base support for footprint of the OSP cabinets. The footprint on the plinth refers to the base area of the cabinet, which must be precisely aligned with the plinth to ensure stability, load distribution, and proper anchoring, and for cable Management. A key limitation of having different plinth sizes for varying OSP cabinet footprints is the challenge of standardization, increased inventory for different plinths leading to compatibility issues and structural instability.

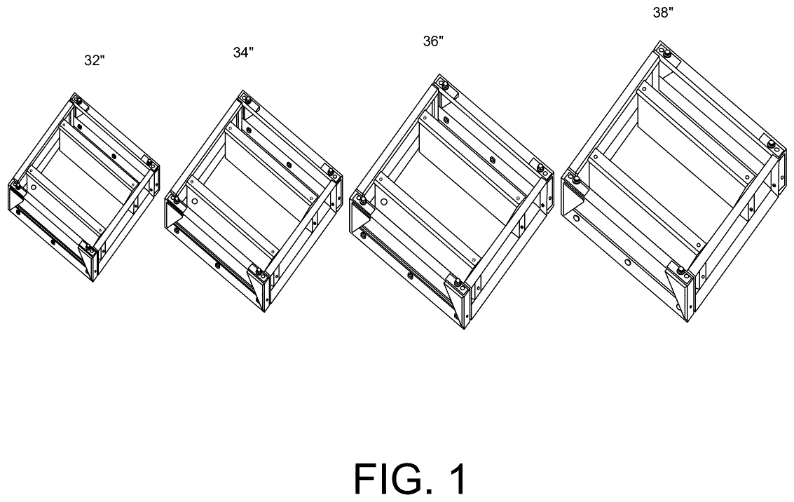

FIG. 1 illustrates perspective views of existing plinth systems. Currently, multiple plinth sizes (e.g., 32″, 34″, 36″, and 38″) may be required to accommodate different cabinet dimensions. This results in separate inventory management, leading to increased storage costs, assembly complexity, and reduced adaptability. Assembly times vary due to the need for different installation procedures. There is a need for a mechanism for standardizing the plinth size to accommodate multiple footprints, which can mitigate the above issues, ensuring easier deployment of OSP cabinets of varying sizes.

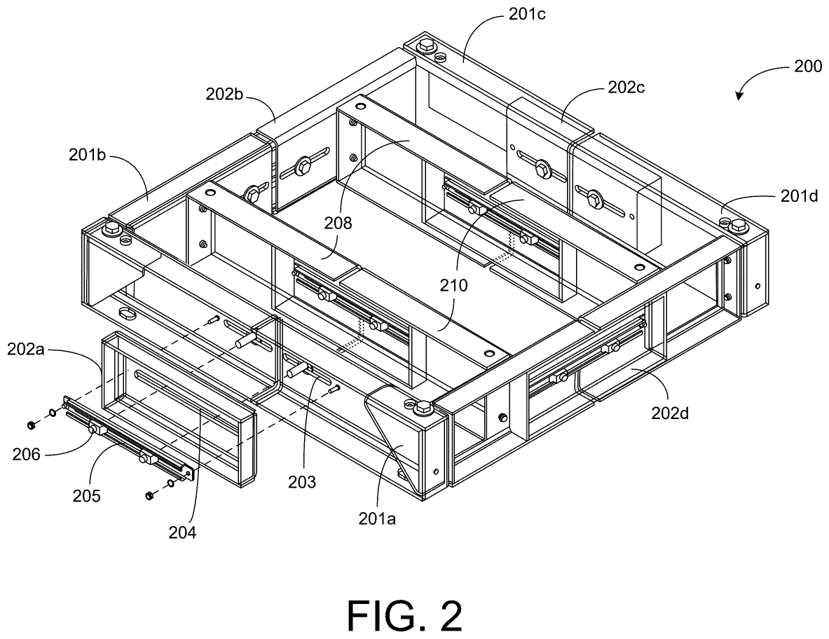

To address these challenges, the present invention provides a modular plinth system that supports multiple cabinet sizes using a single adjustable design. The modular plinth system further reduces inventory requirements, simplifies assembly, and enhances installation efficiency. A more detailed explanation of the modular plinth system is provided with reference to FIG. 2 and forthcoming explanation.

FIG. 2 illustrates a perspective view of a modular plinth system 200, in accordance with an embodiment of the present invention. The modular plinth system 200 may comprise a plurality of plinth modules 201a, 201b, 201c, 201d. In an embodiment, the plinth modules 201a, 201b, 201c, 201d are rectangular channel plinth modules. The plurality of rectangular channel plinth modules 201a, 201b, 201c, 201d can be aligned adjacently at a selected distance from each other to form an outer frame structure of variable size which can accommodate OSP cabinets of different sizes and also the rectangular channel is for strength purpose In an embodiment, the outer frame structure may be selected from a group consisting of rectangular or square shapes. Further, the material for the plinth modules can be selected from the group of materials, including metal, composite materials, such as steel, ensuring durability and load-bearing capacity.

Generally, the footprints of the OSP cabinets are either in a square or rectangular shape, for which rectangular channel plinth modules are preferred, which can be aligned together to provide varying sizes of frame structure to accommodate varying footprints of the OSP cabinets. In an embodiment, each plinth module 201a, 201b, 201c, 201d has at least one plinth sliding slot 203, which facilitates secure attachment to at least one support bracket 202a, 202b, 202c, 202d. The support brackets 202a, 202b, 202c, 202d facilitate proper alignment as per the plinth modules 201a, 201b, 201c, 201d, and structural stability of the modular plinth system, which can be used for adjustment of the plinth as per different footprint sizes of the cabinet.

In an exemplary embodiment, the rectangular channel plinth modules have perpendicular extending walls, wherein each wall includes a plinth sliding slot 203. For example, when a square frame structure of a particular size needs to be prepared, four rectangular channel plinth modules are arranged at a selected distance from each other, thereby forming a desired size of square frame. By placing the rectangular channel plinth modules in the square arrangement, the plinth sliding slot 203 of each of the adjacent walls of plinth modules is aligned on a common plane. In order to securely align the adjacently placed plinth modules, the one or more support brackets 202a, 202b, 202c, 202d are provided.

In an embodiment, each support bracket 202a, 202b, 202c, 202d is mounted over the outer side wall of adjacently placed two rectangular channel plinth modules 201a, 201b, 201c, 201d, in all 4 directions, ensuring a firm connection of the frame structure. In an embodiment, each of the support brackets 202a, 202b, 202c, 202d further includes a bracket sliding slot 204, a bracket 205 or bracket body, and a fastening mechanism 206, allowing for precise positioning and fastening to the rectangular channel plinth modules 201a, 201b, 201c, 201d.

In an exemplary embodiment, when the support bracket 202a or bracket body is placed over the adjacently placed rectangular channel plinth modules 201a, 201b, the plinth sliding slots 203 of the plinth modules 201a, 201b and the bracket sliding slot 204 are aligned on a common plane for fastening (e.g., the bracket body configured to receive the fastening mechanism). Upon placing the support bracket 202a over the walls of the plinth modules 201a, 201b, the support bracket 202a is fastened with the walls of the plinth modules 201a, 201b using the bracket 205 and the fastening mechanism 206 in a tight arrangement. In embodiments, the fastening mechanism is removably coupled to the support bracket.

Similarly, the above arrangement of the support brackets 202a, 202b, 202c, 202d with the plinth modules 201a, 201b, 201c, 201d in all four directions to rigidly form a support structure of varying sizes for OSP cabinets.

The interaction between the plinth sliding slot 203 and the bracket sliding slot 204 ensures a secure and adjustable assembly, accommodating variations in frame size. In one embodiment, the fastening mechanism 206 includes a bolt-type fastening member, such as a T-bolt assembly configured to securely engage both the bracket sliding slot 204 and the plinth sliding slot 203, thereby locking the rectangular channel plinth modules 201a and 201b in a desired position while allowing for easy adjustments. The

In a further embodiment, the modular plinth system 200 may further comprise supporting blocks 208, 210 mounted within the outer frame structure, configured to provide additional structural support to the modular plinth system 200. In one embodiment, the supporting blocks 208, 210 are made of steel to provide structural strength and stability. In an exemplary embodiment, the supporting blocks 208, 210 may also comprise sliding slots, which can be aligned with additional support brackets as explained above, for adjustment according to the size of the outer frame structure.

For example, in an outdoor telecommunications setup, the modular plinth system 200 is used to support OSP (Outside Plant) cabinets. The plurality of rectangular channel plinth modules 201a, 201b, 201c, 201d are aligned adjacently at a selected distance to form an outer frame structure. To accommodate different cabinet sizes, the system allows for adjustable spacing between the plinth modules.

During installation, the fastening mechanism 206, such as a nut assembly, is initially loosely engaged, allowing relative movement between the bracket sliding slot 204 and the plinth sliding slot 203 (loosening the fastening mechanism allows sliding movement). As a result, the rectangular channel plinth modules 201a and 201b may be adjusted by sliding along the slots to achieve the desired spacing. When an extended configuration is required—such as increasing the frame size from 32 inches to 38 inches—the second plinth module 201b is moved outward accordingly.

Once the desired position is reached, the nut assembly of the fastening mechanism 206 is tightened, securing the bracket 205 and locking the plinth modules in place. This ensures structural stability and a firm foundation for supporting OSP cabinets while maintaining flexibility for future adjustments.

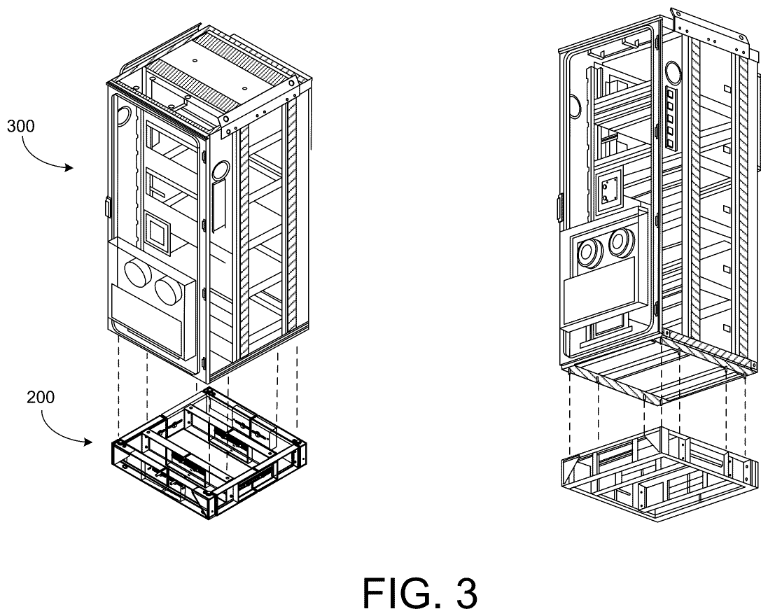

FIG. 3 illustrates a perspective view of the modular plinth system 200 configured to support an Outside Plant (OSP) cabinet 300, in accordance with an embodiment of the present invention. The modular plinth system 200 is designed to provide structural reinforcement, load distribution, cable entry, and stability to the OSP cabinet 300. The modular plinth system 200 facilitates secure attachment of the OSP cabinet 300 through precisely positioned fasteners and interlocking connectors. The modular plinth system 200 further allows for easy installation, alignment, and maintenance, ensuring enhanced durability and adaptability for various deployment environments.

The systems and devices discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent that more than one occurrence or use of the items A, B, or C is possible, multiple uses of A, B, and/or C may form part of the contemplated combinations. For example, a list of “at least one of A, B, and C” may also include AA, AAB, AAA, BB, etc.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as a limitation on the scope of the disclosure.

What is claimed is:

1. A modular plinth system, comprising:
a plurality of plinth modules,
wherein each of the plurality of the plinth modules is aligned adjacently at a selected distance from each other to form an outer frame structure of variable size,
wherein an outer side wall of each of the plurality of the plinth modules includes at least one plinth sliding slot; and
a plurality of support brackets,
wherein each of the support brackets includes a bracket sliding slot, and a bracket with one or more fastening mechanisms,
wherein each of the support brackets is placed over the outer side walls of two adjacent plinth modules to align at least one plinth sliding slot with the bracket sliding slot, and fasten the at least one plinth sliding slot with the bracket sliding slot using the bracket with one or more fastening mechanisms.

2. The modular plinth system as claimed in claim 1, wherein the plinth modules are rectangular channel plinth modules.

3. The modular plinth system as claimed in claim 1, wherein the outer frame structure includes a shape selected from at least one of a square shape or a rectangular shape.

4. The modular plinth system as claimed in claim 1, wherein each support bracket is configured to be placed over the outer side walls of two adjacent plinth modules.

5. The modular plinth system as claimed in claim 1, wherein the bracket sliding slot is provided on the support bracket to align with the plinth sliding slot provided on the plinth module.

6. The modular plinth system as claimed in claim 1, wherein the fastening mechanism comprises a bolt-type fastening member.

7. The modular plinth system as claimed in claim 6, wherein the bolt-type fastening member comprises a T-bolt assembly configured to engage both the bracket sliding slot and the plinth sliding slot.

8. The modular plinth system as claimed in claim 1, wherein each plinth sliding slot is provided on the outer side wall of a corresponding plinth module.

9. The modular plinth system as claimed in claim 1, wherein each support bracket includes a bracket body configured to receive the fastening mechanism.

10. The modular plinth system as claimed in claim 1, wherein the fastening mechanism is removably coupled to the support bracket.

11. The modular plinth system as claimed in claim 1, wherein the plurality of plinth modules together define the outer frame structure.

12. The modular plinth system as claimed in claim 1, wherein each plinth module comprises perpendicular extending walls, and wherein each of the perpendicular extending walls includes a corresponding plinth sliding slot.

13. The modular plinth system as claimed in claim 1, wherein, in a square arrangement of four plinth modules, plinth sliding slots of adjacent walls of the plinth modules are aligned on a common plane.

14. The modular plinth system as claimed in claim 1, wherein the fastening mechanism comprises a nut assembly configured to be tightened to lock the plinth modules in a desired position.

15. The modular plinth system as claimed in claim 1, further comprising one or more supporting blocks mounted within the outer frame structure and configured to provide additional structural support to the modular plinth system.

16. The modular plinth system as claimed in claim 15, wherein the one or more supporting blocks comprise one or more supporting block sliding slots alignable with a support bracket to adjust according to a size of the outer frame structure.

17. A modular plinth system, comprising:
a plurality of rectangular channel plinth modules, wherein the rectangular channel plinth modules are aligned adjacently at a selected distance from each other to form an outer frame structure, wherein the outer frame structure is selected from a square shape or a rectangular shape, wherein each rectangular channel plinth module includes perpendicular extending walls, and wherein each wall includes at least one plinth sliding slot provided on an outer side wall of the plinth module; and
a plurality of support brackets, wherein one or more support brackets or the plurality of support brackets are placed over the outer side walls of two adjacently placed rectangular channel plinth modules, wherein the one or more support brackets comprises:
a bracket body:
a bracket sliding slot, wherein the plinth sliding slots of the rectangular channel plinth modules and the bracket sliding slot of the support bracket are aligned on a common plane: and
a fastening mechanism, wherein the fastening mechanism comprises a bolt-type fastening member including a nut assembly, wherein loosening the fastening mechanism allows sliding movement of the rectangular channel plinth modules to adjust the selected distance, and tightening the nut assembly locks the rectangular channel plinth modules in a desired position, wherein the support brackets are fastened with the walls of the rectangular channel plinth modules using the bracket body and the fastening mechanism to rigidly form the outer frame structure; and
supporting blocks mounted within the outer frame structure, the supporting blocks providing additional structural support and including sliding slots alignable with the support brackets for adjustment according to a size of the outer frame structure.

18. The modular plinth system as claimed in claim 17, wherein four rectangular channel plinth modules are arranged in a square arrangement, and wherein the plinth sliding slots of adjacent walls of the rectangular channel plinth modules are aligned on a common plane, the supporting blocks are mounted within the outer frame structure to provide structural strength and stability to the modular plinth system during installation of cabinets.

19. The modular plinth system as claimed in claim 18, wherein the fastening mechanism is removably coupled to the support bracket to allow adjustment of the outer frame structure to accommodate different footprint sizes of cabinets.

20. The modular plinth system as claimed in claim 19, wherein the bolt-type fastening member comprises a T-bolt assembly configured to engage both the bracket sliding slot and the plinth sliding slot.
